(19) United States
(12) Patent Application Publication
(10) Pub. No.: US 2026/0320461 A1
(43) Pub. Date: Oct. 15, 2026

(54) QUANTUM CIRCUIT APPARATUS AND CONTROL METHOD

(71) Applicant: NEC Corporation, Tokyo (JP)

(72) Inventor: Yohei KAWAKAMI, Tokyo (JP)

(73) Assignee: NEC Corporation, Tokyo (JP)

(21) Appl. No.: 19/544,021

(22) Filed: Feb. 19, 2026

(30) Foreign Application Priority Data
Feb. 27, 2025 (JP) 2025-030266

(51) Int. Cl. G06N 10/40; H10N 60/12

(52) U.S. Cl. CPC G06N 10/40; H10N 60/12

(57) ABSTRACT

A quantum circuit apparatus includes N qubits, where N is a predetermined integer of 3 or greater, configured to be coupled via a many-body interaction, wherein a parameter representing nonlinearity of at least one of the N qubits has a sign different from the sign of the parameter representing the nonlinearity of the other qubits.

### FIELD

### Cross Reference to Related Applications

The present application is based upon and claims the benefit of the priority of Japanese patent application No. 2025-030266, filed on Feb. 27, 2025, the disclosure of which is incorporated herein in its entirety by reference thereto.

The present disclosure relates to a quantum circuit apparatus and control method.

### BACKGROUND

In an LHZ (Lechner, Hauke, Zoller) scheme which is one approach to quantum annealing for solving combinatorial optimization problems, an interaction of quantum bits (qubits) such as a four-body interaction (Non-Patent Literature 1) is required. Non-Patent Literature 2 discloses as a physical implementation of the LHZ scheme, a network illustrated in FIG. 1, which utilizes a four-body interaction of four qubits via a coupler. FIG. 1 is based on a of FIG. 4 in Non-Patent Literature 2. In the example illustrated in FIG. 1, a Josephson Parametric Oscillator (JPO) is used as a qubit, and the coupler is provided with a Josephson Junction (JJ).

NPL 1: Lechner, Hauke, Zoller, “A quantum annealing architecture with all-to-all connectivity from local interactions”, Science Advances 23 Oct. 2015 Vol 1, Issue 9:DOI: 10.1126/sciadv.1500838 NPL 2: Shruti Puri, Christian Kraglund Andersen, Arne L. Grimsmo, Alexandre Blais, “Quantum annealing with a network of all-to-all connected, two-photon driven Kerr nonlinear oscillators”, Nature Commun 8, 15785 (2017)

### SUMMARY

The quantum circuit apparatus in FIG. 1 includes a coupler provided with a nonlinear element such as a Josephson junction. Setting and adjustment of a resonance frequency of the coupler requires additional measuring equipment(s), designing of a waveguide(s) and so forth. Increasing a coupling coefficient (coupling strength) of a four-body interaction of four qubits would be accompanied by a manufacturing challenge ascribable to, for example, difference in parameters of Josephson junctions used in the qubits and the coupler.

One of objects of the present disclosure is to provide a quantum circuit apparatus and a control method, each enabling to solve the above-described issue.

According to one aspect of the present disclosure, a quantum circuit apparatus includes N qubits, where N is a predetermined integer of 3 or greater, configured to be coupled via a many-body interaction, wherein at least one of the N qubits is configured to have a sign of a parameter representing nonlinearity thereof different from a sign of a parameter representing nonlinearity of at least one other of the N qubits.

According to one aspect of the present disclosure, there is provided a control method of a quantum circuit that includes N qubits, where N is a predetermined integer of 3 or more, enabled to be coupled via a many-body interaction, wherein the method includes setting a sign of a parameter representing nonlinearity of at least one of the N qubits to be different from a sign of a parameter representing nonlinearity of at least one other of the N qubits, to increase a coupling coefficient of the many-body interaction of the N qubits.

According to the present disclosure, adjustment such as setting a resonance frequency of a coupler is made unnecessary and a coupling coefficient of a four-body interaction can be increased.

### BRIEF DESCRIPTION OF THE DRAWINGS

FIG. 1 is a diagram illustrating an example of the disclosure of Non-Patent Literature 2.

FIG. 2 is a diagram illustrating a configuration of at least one example of embodiments of the present disclosure.

FIG. 3 is a diagram illustrating the configuration of at least one example of embodiments of the present disclosure.

FIG. 4 is a diagram illustrating the configuration of at least one example of embodiments of the present disclosure.

FIG. 5 is a diagram illustrating the configuration of at least one example of embodiments of the present disclosure.

FIG. 6 shows one example of embodiments of the present disclosure.

FIG. 7 is a diagram illustrating the configuration of at least one example of embodiments of the present disclosure.

FIG. 8A to FIG. 8C are diagrams illustrating the configuration of at least one example of embodiments of the present disclosure.

FIG. 9 is a diagram illustrating at least one example of embodiments of the present disclosure.

### DETAILED DESCRIPTION

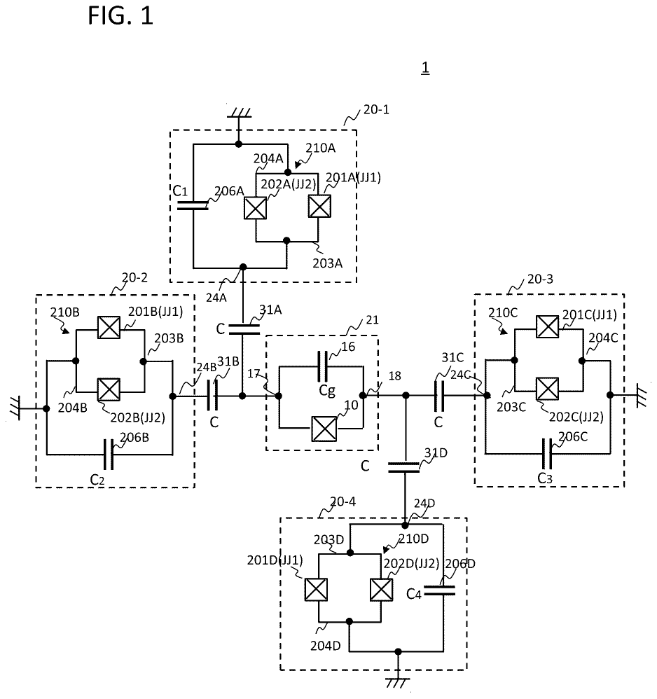

The following describes embodiments of the present disclosure. First, as a premise for the present disclosure, an analysis of a configuration illustrated in FIG. 1 is provided and its issue is described. Referring to FIG. 1, a quantum circuit apparatus 1 includes four qubits 20-1 to 20-4 and a coupler 21. More specifically, the first qubit 20-1 includes a superconducting member 203A that is set in a superconducting state at an extremely low (cryogenic) temperature, a Josephson Junction 201A, a superconducting member 204A, and a Josephson Junction 202A, which together form a loop constituting a SQUID 210A. The superconducting member 203A is connected to an electrode 24A, the superconducting member 204A is connected to ground. A capacitor 206A (shunt capacitor) is connected in parallel with the SQUID 210A between the electrode 24A and ground. In operation, a magnetic flux penetrating the SQUID 210A is generated by a pump signal (current) supplied from an unillustrated signal source to flow through an unillustrated inductor (magnetic field generation part). A resonance angular frequency ω₁ of the first qubit 20-1 is varied according to the magnetic flux penetrating the SQUID 210A. For the second through fourth qubits 20-2 to 20-4, respectively, superconducting members 203B to 203D corresponding to the superconducting member 203A of the first qubit 20-1, Josephson Junctions 201B to 201D corresponding to Josephson Junction 201A of the first qubit 20-1, superconducting members 204B to 204D corresponding to the superconducting member 204A of the first qubit 20-1, Josephson Junctions 202B to 202D corresponding to the Josephson Junction 202A of the first qubit 20-1, SQUIDs 210B to 210D corresponding to the SQUID 210A of the first qubit 20-1, and capacitors 206B to 206D corresponding to the capacitor 206A of the first qubit 20-1 are provided. When operated, a magnetic flux penetrating each of the SQUIDs 210B to 210D is generated by a pump signal (current) supplied from an unillustrated signal source through an unillustrated inductor (magnetic field generation part) to ground. Resonance angular frequencies ω₂ to ω₄ of the second to fourth qubits 20-2 to 20-4 are varied according to the magnetic flux penetrating the SQUIDs 210B to 210D.

The coupler 21 includes a Josephson junction 10 and a capacitor 16 connected in parallel between a first electrode (first node) 17 and a second electrode (second node) 18. The first electrode 17 is coupled to the first qubit 20-1 and the second qubit 20-2 via coupling capacitors 31A and 31B (capacitive coupling), and the second electrode 18 is connected to the third qubit 20-3 and the fourth qubit 20-4 via coupling capacitors 31C and 31D (capacitively coupled). Note that in the following, when there is no need to discriminate a qubit, a branch number of a reference sign of the qubit is omitted, and a qubit it is referred to as the qubit 20. The same applies to other elements.

For the circuit illustrated in FIG. 1, angular frequencies of respective pump signals are configured as follows, as a condition for the four-body interaction of the first to fourth qubits 20-1 to 20-4 (JPO1 to JPO4) Non-Patent Literature (NPL) 2.

ω_{p,1}+ω_{p,2}=ω_{p,3}+ω_{p,4} (1)

where ω_{p,i} (i=1, 2, 3, 4) is an angular frequency of a pump signal supplied to an i-th qubit 20-i. An alternating signal with an angular frequency approximately twice a resonance angular frequency ωᵢ of the i-th qubit 20-i is supplied as the pump signal to the i-th qubit 20-i.

Regarding the circuit illustrated in FIG. 1, in a Hamiltonian in a rotating frame, i.e., a rotating wave approximation (RWA), a coupling term for a four-body interaction of the four qubits 20-1 to 20-4 through the coupler 21 may be given by the following equation (2) (e.g., NPL 2).

$${g}^{( 4 )} ( {a}_{1}^{†} {a}_{2}^{†} {a}_{3} {a}_{4} + {a}_{4}^{†} {a}_{3}^{†} {a}_{2} {a}_{1} ) \qquad ( 2 )$$

In equation (2), aᵢ and aᵢ⁺ (i=1, 2, 3, 4) represent annihilation and creation operators for a boson at each qubit, respectively. Note that in NPL 2, a coupling term for the four-body interaction in the Hamiltonian takes a negative sign in equation (2).

In equation (2), a coupling strength (coupling coefficient) g⁽⁴⁾ of the four-body interaction is given by:

$${g}^{( 4 )} = {K}_{g} \frac{{g}_{1} {g}_{2} {g}_{3} {g}_{4}}{{Δ}_{1} {Δ}_{2} {Δ}_{3} {Δ}_{4}} \qquad ( 3 )$$

The coupling coefficient g⁽⁴⁾ depends on nonlinearity of the Josephson Junction 10 in the coupler 21 and a difference (detuning) between the resonance frequencies of each of the qubits 20-1 to 20-4 and the coupler 21.

In equation (3),
K_{g} is a parameter (Kerr coefficient) representing nonlinearity (Kerr nonlinearity) of the coupler 21. K_{g} is also referred to as a nonlinear parameter of the coupler 21.
Δᵢ (i=1, 2, 3, 4) is a difference (detuning) between the resonance angular frequency ω_{c} of the coupler 21 and the resonance angular frequency ωᵢ of the i-th quantum bit 20-i (=ω_{c}−ωᵢ).
gᵢ (i=1, 2, 3, 4) is a coupling coefficient between the i-th qubit 20-i and the coupler 21.

From equation (3), by configuring the detuning Δᵢ as small as possible within a range:

$$\frac{{g}_{i}}{{Δ}_{i}} < 1 ( i = 1 , 2 , 3 , 4 ) \qquad ( 4 )$$

the four-body interaction coupling coefficient g⁽⁴⁾ can be made large, thereby strengthening the four-body interaction. Therefore, the resonance angular frequency ωᵢ (i=1, 2, 3, 4) of each qubit 20-i and the resonance angular frequency ω_{c} of the coupler 21 are set to be sufficiently close.

In equation (3), approximating each gᵢ/Δᵢ (i=1, 2, 3, 4) with g/Δ gives:

$$\frac{{g}_{i}}{{Δ}_{i}} \approx \frac{g}{Δ} ( i = 1 , 2 , 3 , 4 ) \qquad ( 5 )$$

In equation (3), g⁽⁴⁾ corresponds to the nonlinear parameter K_{g} of the coupler 21 multiplied by the fourth power term of g/Δ:(g/Δ)⁴.

From equation (3), increasing the nonlinear parameter K_{g} of the coupler 21 results in a larger coupling coefficient g⁽⁴⁾ of the four-body interaction. However, the nonlinear parameter K_{g} of the coupler 21 is multiplied by (g/Δ)⁴, which is less than 1. Therefore, the coupling coefficient g⁽⁴⁾ of the four-body interaction can only be a small value in principle. That is, in the circuit of FIG. 1, it is basically difficult to make the coupling coefficient g⁽⁴⁾ of the four-body interaction large.

When using the nonlinear element Josephson junction 10 as a fixed-frequency coupler 21, as illustrated in the circuit of FIG. 1, its resonance frequency depends on a critical current value of the Josephson junction 10. Therefore, fabricating a Josephson junction with a critical current value close to a desired value (design value) is required.

On the other hand, if the coupler 21 is not a fixed-frequency type but instead, a variable frequency type equipped with, for example, a Superconducting Quantum Interference Device (SQUID), it becomes necessary to provide an input/output line for reading a frequency of the coupler and a bias line for changing and/or adjusting the frequency of the coupler (e.g., a line supplying a bias signal to generate a bias magnetic flux applied to the SQUID).

In addition to placing these lines on a chip with a network of qubits 20 and couplers 21 integrated thereon, measurement wiring/cables, signal sources, and measuring instruments are required outside the chip. Furthermore, a specified high precision is required for adjusting a difference in resonance frequencies between the coupler and each of the qubits.

The above issue is described as one example. According to the present disclosure, a many-body interaction due to nonlinearity of qubits may be implemented without a coupler, in various cases not limited to the above, allowing a coupling coefficient of the many-body interaction to be configured to a desired value.

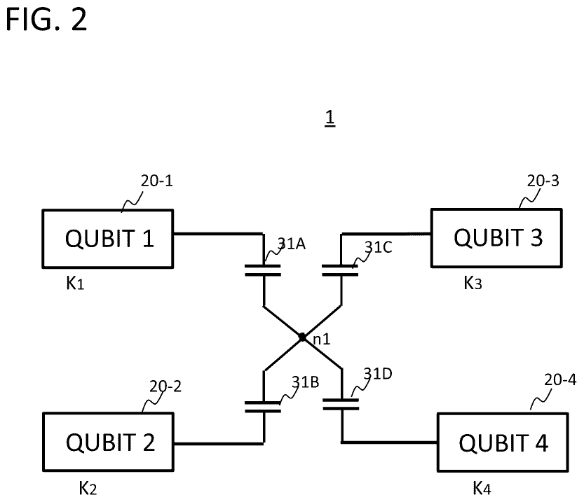

FIG. 2 is an illustrative diagram of an example of embodiments of the present disclosure. FIG. 2 is an illustrative diagram of an example of embodiments of the present disclosure. As illustrated in FIG. 2, even in a configuration without a coupler, a four-body interaction of qubits can be realized, that is, four qubits are enabled to be coupled via a four-body interaction. Referring to FIG. 2, there are provided first to fourth qubits 20-1 to 20-4 coupled via a four-body interaction. K₁ to K₄ are parameters representing nonlinearity of the first to fourth qubits 20-1 to 20-4. At least one of the first to fourth qubits 20-1 to 20-4 is configured to have a sign of the parameter representing nonlinearity different from signs of parameters representing nonlinearity of remaining qubits. The qubits 20-1 through 20-4 are capacitively coupled to a common node n1 via coupling capacitors 31A through 31D, respectively.

In FIG. 2, when a coupling coefficient of a four-body interaction induced by the nonlinearity of the first to fourth qubits 20-1 to 20-4 is represented for example, by a term including a difference between parameters representing the nonlinearity of the first and second qubits (e.g., K₂−K₁), and a term including a difference between the parameters representing the nonlinearity of the third and fourth qubits (K₃−K₄), signs of the parameters K₂ and K₁, which represent the nonlinearity of the first and second qubits respectively, may be set to be opposite each other to each other, signs of parameters K₃ and K₄, which represent the nonlinearity of the third and fourth qubits respectively, may be set to be opposite each other to each other, and the coupling coefficient of the four-body interaction of the first to fourth qubits may be set to be large.

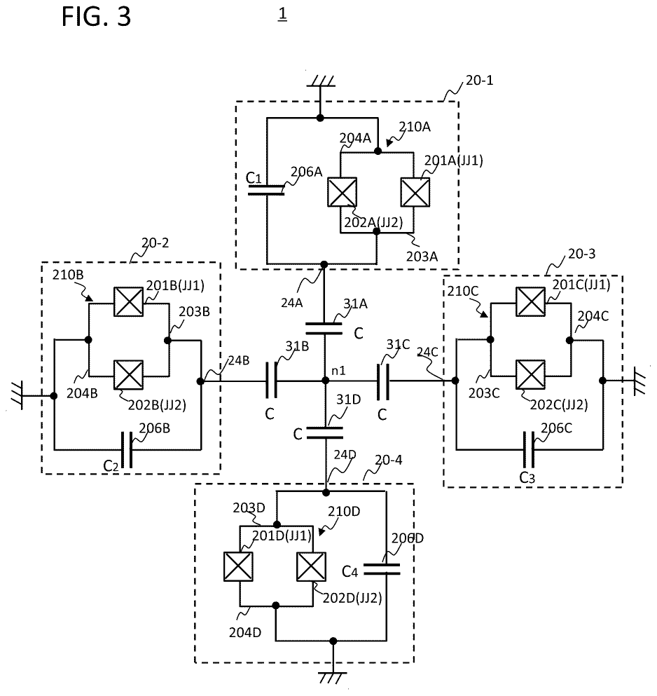

FIG. 3 is a diagram illustrating an example circuit configuration of FIG. 2. The following describes the example circuit configuration and derivation of the coupling coefficient of the four-body interaction induced by nonlinearity of qubits 20.

Referring to FIG. 3, in the quantum circuit apparatus 1, the first qubit 20-1 includes a superconducting member 203A that is set in a superconducting state at an extremely low (cryogenic) temperature, a Josephson Junction 201A, a superconducting member 204A, and a Josephson Junction 202A, which together form a loop constituting a SQUID 210A. The superconducting member 203A is connected to the electrode 24A, the superconducting member 204A is connected to ground, and a capacitor 206A (shunt capacitor) is connected in parallel with the SQUID 210A between the electrode 24A and ground. In operation, a magnetic flux penetrating the SQUID 210A is generated by a current provided by an unillustrated signal source to flow through an unillustrated inductor (magnetic field generation part). The resonance angular frequency ω₁ of the first qubit 20-1 is varied according to the magnetic flux penetrating the SQUID 210A. For the second through fourth qubits 20-2 to 20-4, respectively, superconducting members 203B to 203D corresponding to the superconducting member 203A of the first qubit 20-1, Josephson Junctions 201B to 201D corresponding to Josephson Junction 201A of the first qubit 20-1, superconducting members 204B to 204D corresponding to the superconducting member 204A of the first qubit 20-1, Josephson Junctions 202B to 202D corresponding to the Josephson Junction 202A of the first qubit 20-1, SQUIDs 210B to 210D corresponding to the SQUID 210A of the first qubit 20-1, and capacitors 206B to 206D corresponding to the capacitor 206A of the first qubit 20-1 are provided. When operated, a magnetic flux penetrating each of the SQUIDs 210B to 210D is generated by a current flowing from an unillustrated signal source through an unillustrated inductor (magnetic field generation part) to ground. Resonance angular frequencies ω₂ to ω₄ of the second to fourth qubits 20-2 to 20-4 are varied according to the magnetic flux penetrating the SQUIDs 210B to 210D.

A four-body interaction may be induced by nonlinearity (Kerr nonlinearity) of the four qubits 20-1 to 20-4. In this case, the coupling coefficient h⁽⁴⁾, which represents a coupling coefficient of the four-body interaction, is given (approximated) by the following equation (6).

$${h}^{( 4 )} ≃ 2 {g}_{12} {g}_{13}^{2} \frac{( {K}_{2} - {K}_{1} ) {Δ}_{34} + ( {K}_{3} - {K}_{4} ) {Δ}_{12}}{{Δ}_{12} {Δ}_{13} {Δ}_{14} {Δ}_{34}} \qquad ( 6 )$$

In equation (6),
gᵢⱼ (i≠j=1, 2, 3, 4) is a strength (magnitude) of coupling between the i-th qubit 20-i and the j-th qubit 20-j.
Δᵢⱼ (i≠j=1, 2, 3, 4) is a difference ωᵢ−ωⱼ between the resonance angular frequency ωᵢ of the i-th qubit 20-i and the resonance angular frequency ωⱼ of the j-th qubit 20-j.
Kᵢ (i=1, 2, 3, 4) is a parameter (Kerr coefficient) representing nonlinearity (Kerr nonlinearity) of the i-th qubit 20-i. Kᵢ is also referred to as a nonlinear parameter of qubit 20-i.

Kᵢ may correspond to Kerr nonlinearity of the i-th qubit (JPO) 20-i in a Hamiltonian Hi of the i-th qubit (JPO) 20-i (i=1, 2, 3, 4) in FIG. 2 expressed by the following equation (7).

$$H i = Δ {a}_{i}^{+} {a}_{i} - {K}_{i} ( {a}_{i}^{+ 2} {a}_{i}^{2} ) + {E}_{p} ( {a}_{i}^{+ 2} + {a}_{i}^{2} ) \qquad ( 7 )$$

In equation (7),
Δ is a difference between the resonance angular frequency ω_{c} of the coupler 21 and half the angular frequency op of the i-th pump signal:

0=ω_{c}−(½)ωp (8)
Ep is a two-photon drive strength (pump term).
aᵢ⁺ and aᵢ are creation and annihilation operators for a boson (photon) in the i-th qubit 20-i.

The four-body interaction of the four qubits 20-1 to 20-4 arises not through the coupler 21, but from nonlinearity of the qubit 20. Referring again to FIG. 2, the coupling coefficient h⁽⁴⁾ for the four-body interaction induced by the nonlinearity of qubits may be expressed (or approximated) as the following equation (9).

$$\frac{{h}^{( 4 )}}{2} ≃ {\sum }_{i = 1}^{4} {\prod }_{\begin{matrix}j = 1 \\ ( j \neq i )\end{matrix}}^{4} ( \frac{{g}_{i j}}{{Δ}_{j i}} ) {K}_{i} \qquad ( 9 )$$

In equation (9), similar to equation (6),
gᵢⱼ (i,j=1, 2, 3, 4(j≠i)) is a strength (magnitude) of coupling between the j-th qubit 20-j and the i-th qubit 20-j (also called the “coupling constant”).
Δⱼᵢ (i,j=1, 2, 3, 4 (j≠i)) is a difference ωⱼ−ωᵢ between the resonance angular frequency ωⱼ of the j-th qubit 20-j and the resonance angular frequency ωᵢ of the i-th qubit 20-i.
Kᵢ (i=1, 2, 3, 4) is the nonlinear parameter of the i-th qubit 20-i.

In equation (9), a multiplicative term:

$${\prod }_{\begin{matrix}j = 1 \\ ( j \neq i )\end{matrix}}^{4} ( \frac{{g}_{i j}}{{Δ}_{j i}} ) {K}_{i}$$

may be expressed by the following equation (10), when gᵢⱼ (j=1, 2, 3, 4 (j≠i)) is denoted as g, Δⱼᵢ (j=1, 2, 3, 4 (j≠i)) as Δ, and K_{q} as an effective value of gᵢⱼ/Δⱼᵢ (including a sign, i.e., an effective Kerr coefficient remaining after cancelled out with signs ±).

$${( \frac{g}{Δ} )}^{3} {K}_{q} \qquad ( 10 )$$

In equation (10), the following is assumed.

$$\frac{g}{Δ} < 1 \qquad ( 11 )$$

Under the above condition, configuring the difference Δ in the resonance angular frequency between the two qubits 20 as small as possible makes a value of the left side in equation (inequality) (11) large.

From equation (10), increasing the nonlinearity parameter K_{q} of the qubit 20 also increases the four-body interaction coefficient h⁽⁴⁾. In equation (10), the nonlinearity parameter K_{q} of the qubit 20 is multiplied by the cubic term (g/Δ)³ of (g/Δ) (<1). Therefore, the coupling coefficient h⁽⁴⁾ of the four-body interaction due to the nonlinearity of the qubit 20 can be made larger, as compared to g⁽⁴⁾ (equation (3)) for FIG. 1. For example, when K_{q} and K_{g} are of the same order of magnitude, h⁽⁴⁾ can potentially be nearly one order of magnitude larger than g⁽⁴⁾ in equation (3).

Equation (9) representing the four-body interaction due to the nonlinearity of the qubit 20 does not involve a degree of freedom of the coupler 21 (parameters related to the coupler 21). Therefore, adjustment of a resonance frequency of the coupler 21 is not required to strengthen the four-body interaction. In other words, the coupler 21 is not required to include a nonlinear element such as a Josephson junction or a SQUID and may be configured using a linear element(s). When the coupler 21 is configured using a linear element(s), a signal source to vary a frequency of a coupler 21, a control line and ab input/output line, and installation of measuring equipment(s) are not required. Note that while a degree of freedom of the coupler 21 (parameters related to the coupler 21, etc.) is not involved, equation (9) representing the four-body interactions due to nonlinearity of qubits 20 do not preclude a coupler 21 constructed with a nonlinear element(s) such as a Josephson junction(s). Furthermore, when the coupler 21 is employed to generate an interaction among the qubits 20, including a four-body interaction, the four-body interaction represented by equation (3) and the four-body interaction represented by equation (9) can coexist.

In equation (9), focusing on i=1, i.e., the first qubit 20-1 in FIG. 2, regarding
the difference Δ₂₁ (=ω₂−ω₁) in a resonance angular frequency between the second qubit 20-2 and the first qubit 20-1, and the coupling coefficient g₁₂ between the first qubit 20-1 and the second qubit 20-2,
the difference Δ₃₁ (=ω₃−ω₁) in a resonance angular frequency between the third qubit 20-3 and the first qubit 20-1, and the coupling coefficient g₁₃ between the first qubit 20-1 and the third qubit 20-3,
the difference Δ₄₁ (=ω₄−ω₁) in a resonance angular frequency between the fourth qubit 20-4 and the first qubit 20-1, and the coupling coefficient g₁₄ between the first qubit 20-1 and the fourth qubit 20-4, the multiplication term for i=1 in equation (9) is given as the following equation.

$$( \frac{{g}_{12}}{{Δ}_{21}} ) ( \frac{{g}_{13}}{{Δ}_{31}} ) ( \frac{{g}_{14}}{{Δ}_{41}} ) {K}_{1} \qquad ( 12 )$$

Equation (12) is a generalized form of equation (9).

When expanding equation (9) for the first to fourth qubits 20-1 to 20-4 in FIG. 2, we have the following approximate equation (13):

$${h}^{( 4 )} ≃ 2 ( {K}_{1} \frac{{g}_{21}}{{Δ}_{21}} \frac{{g}_{31}}{{Δ}_{31}} \frac{{g}_{41}}{{Δ}_{41}} + {K}_{2} \frac{{g}_{12}}{{Δ}_{12}} \frac{{g}_{32}}{{Δ}_{32}} \frac{{g}_{42}}{{Δ}_{42}} + {K}_{3} \frac{{g}_{13}}{{Δ}_{13}} \frac{{g}_{23}}{{Δ}_{23}} \frac{{g}_{43}}{{Δ}_{43}} + {K}_{4} \frac{{g}_{14}}{{Δ}_{14}} \frac{{g}_{24}}{{Δ}_{24}} \frac{{g}_{34}}{{Δ}_{34}} ) \qquad ( 13 )$$

In equation (13), a condition for the first to fourth qubits 20-1 to 20-4 to be coupled via the four-body interaction (condition concerning the resonance angular frequencies ω₁ to ω₄) may be defined as:

ω₁+ω₂=θ₃+ω₄ (14)

From equation (14), the followings hold.

ω₃−ω₁=−(ω₄−ω₂)

ω₄−ω₁=−(ω₃−ω₂)

Therefore,

Δ₁₃=−Δ₂₄ (15)

Δ₁₄=−Δ₂₃ (16)

Furthermore, regarding equation (13), Δᵢⱼ(=ωᵢ−ωⱼ) is antisymmetric with respect to indices i and j

Δᵢⱼ=−Δⱼᵢ (17)

gᵢⱼ is symmetric with respect to indices i and j:

gᵢⱼ=gⱼᵢ (18)

The coupling constant g₁₂ between the first and second qubits 20-1 and 20-2 coupled to the node (common node) 1 via coupling capacitors 31A and 31B, and the coupling constant g₃₄ between the third and fourth qubits 20-3 and 20-4 coupled to the node 1 via coupling capacitors 31C and 31D may well be approximated to be equal to each other when their respective resonance angular frequencies are close.

g₁₂=g₃₄ (19)

The coupling constant g₁₃ between the first and third qubits 20-1 and 20-3, the coupling constant g₁₄ between the first and fourth qubits 20-1 and 20-4, and the coupling constant g₂₃ between the second and third qubits 20-2 and 20-3, and the coupling constant g₂₄ between the second and fourth qubits 20-2 and 20-4 may well be approximated to be equal to each other when their mutual resonance angular frequencies are close.

g₁₃=g₁₄=g₂₃=g₂₄ (20)

Under the conditions of equations (15) to (20), equation (13) becomes.

$${h}^{( 4 )} ≃ 2 {g}_{12} {g}_{13}^{2} \{ {K}_{1} \frac{- 1}{{Δ}_{12} {Δ}_{13} {Δ}_{14}} + {K}_{2} \frac{1}{{Δ}_{12} {Δ}_{23} {Δ}_{24}} + {K}_{3} \frac{- 1}{{Δ}_{13} {Δ}_{23} {Δ}_{34}} + {K}_{4} \frac{1}{{Δ}_{14} {Δ}_{24} {Δ}_{34}} \} = - 2 {g}_{12} {g}_{13}^{2} ( {K}_{1} \frac{{Δ}_{34}}{{Δ}_{12} {Δ}_{13} {Δ}_{14} {Δ}_{34}} + {K}_{2} \frac{- {Δ}_{34}}{{Δ}_{12} {Δ}_{13} {Δ}_{14} {Δ}_{34}} + {K}_{3} \frac{- {Δ}_{12}}{{Δ}_{12} {Δ}_{13} {Δ}_{14} {Δ}_{34}} + {K}_{4} \frac{{Δ}_{12}}{{Δ}_{12} {Δ}_{13} {Δ}_{14} {Δ}_{34}} ) \qquad ( 21 )$$

From above, equation (6) repeated below is derived.

$${h}^{( 4 )} ≃ 2 {g}_{12} {g}_{13}^{2} \frac{( {K}_{2} - {K}_{1} ) {Δ}_{34} + ( {K}_{3} - {K}_{4} ) {Δ}_{12}}{{Δ}_{12} {Δ}_{13} {Δ}_{14} {Δ}_{34}} \qquad ( 6 )$$

From equation (6), when the nonlinear parameter K₁ of the first qubit 20-1 is equal to the nonlinear parameter K₂ of the second qubit 20-2, and the nonlinear parameter K₃ of the third qubit 20-3 is equal to the nonlinear parameter K₄ of the fourth qubit 20-4, that is, when

K₂=K₁, K₃=K₄ (22)

holds, then h⁽⁴⁾ becomes 0.

From equation (6), to obtain a nonzero value for the coefficient h⁽⁴⁾ of the four-body interaction induced by the nonlinearity of the first through fourth qubits 20-1 to 20-4, it is necessary to configure nonlinear parameters Kᵢ (i=1, 2, 3, 4) with distinct values.

In equation (6), by changing a sign (positive or negative) of any one of (or multiple) nonlinear parameters Kᵢ (i=1, 2, 3, 4) of the first to fourth qubits 20-1 to 20-4, for example, by appropriately setting the nonlinear parameters K₁ to K₄ of the first to fourth qubits 20-1 to 20-4, and the differences Δ₃₄ and Δ₁₂ in the resonance angular frequencies, such that any one of the following conditions is met:

((K₂−K₁)>0 and Δ₃₄>0) and ((K₃−K₄)>0 and Δ₁₂>0) (23a)

((K₂−K₁)>0 and Δ₃₄<0) and ((K₃−K₄)>0 and Δ₁₂<0) (23b)

((K₂−K₁)<0 and Δ₃₄>0) and ((K₃−K₄)<0 and Δ₁₂>0) (23c)

((K₂−K₁)<0 and Δ₃₄<0) and ((K₃−K₄)<0 and Δ₁₂<0) (23d)

((K₂−K₁)<0 and Δ₃₄>0) and ((K₃−K₄)>0 and Δ₁₂<0) (23e)

((K₂−K₁)>0 and Δ₃₄<0) and ((K₃−K₄)<0 and Δ₁₂>0) (23f),

the coefficient h⁽⁴⁾ of the four-body interaction in equation (6) does not become zero.

When the nonlinear parameters K₂ and K₁ have the same sign, and the nonlinear parameters K₃ and K₄ have the same sign, values of (K₂-K₁) (an absolute value if negative) and (K₃− K₄) (an absolute value if negative) become smaller.

In equations (23a) and (23b), configuring signs of the nonlinear parameters K₂ and K₃ to positive and signs of the nonlinear parameters K₁ and K₄ to negative results in a large value for the coefficient h⁽⁴⁾ of the four-body interaction (when h⁽⁴⁾ is negative, its absolute value becomes large).

In equations (23c) and (23d), configuring signs of the nonlinear parameters K₂ and K₃ to negative and signs of the nonlinear parameters K₁ and K₄ to positive results in a large value for the coefficient h⁽⁴⁾ of the four-body interaction (when h⁽⁴⁾ is negative, its absolute value becomes large).

In equation (23e), configuring a sign of the nonlinear parameter K₂ to negative, a sign of the nonlinear parameter K₁ to positive, a sign of the nonlinear parameter K₃ to positive, and a sign of the nonlinear parameter K₄ to negative results in a large value for the coefficient h⁽⁴⁾ of the four-body interaction (when h⁽⁴⁾ is negative, its absolute value becomes large).

In equation (23f), configuring a sign of the nonlinear parameter K₂ to positive, a sign of the nonlinear parameter K₁ to negative, a sign of the nonlinear parameter K₃ to negative, and a sign of the nonlinear parameter K₄ to positive results in a large value for the coefficient h⁽⁴⁾ of the four-body interaction (when h⁽⁴⁾ is negative, its absolute value becomes large).

When a condition for the resonance angular frequencies ωᵢ to ω₄ of the four qubits to be coupled via the four-body interaction, is set as

ω₁+ω₃=ω₂+ω₄ (24)

then equation (13) may be expressed as the following equation (25).

$${h}^{( 4 )} = - 2 {g}_{12} {g}_{13}^{2} \frac{( {K}_{1} - {K}_{3} ) {Δ}_{24} + ( {K}_{4} - {K}_{2} ) {Δ}_{13}}{{Δ}_{12} {Δ}_{13} {Δ}_{14} {Δ}_{24}} \qquad ( 25 )$$

From equation (25), when

K₁=K₄=K>0, K₂=K₃=−K<0 (26a)

or

K₁=K₄=K<0, K₃=K₂=−K>0 (26b)

holds, then,

(K₁−K₃)>0, (K₄−K₂)>0 (27a)

or

(K₁−K₃)<0, (K₄−K₂)<0 (27b)

Thus, setting the differences in resonance angular frequencies Δ₂₄ and Δ₁₃ such that

Δ₂₄>0, Δ₁₃>0 (28a)

or

Δ₂₄<0, Δ₁₃<0 (28b)

may enlarge a value (an absolute value if negative) of a numerator in equation (25): (K₁−K₃)Δ₂₄+(K₄−K₂)Δ₁₃. The coupling coefficient h⁽⁴⁾ of the four-body interaction induced by the nonlinearity of the four qubits 20-1 to 20-4 can be increased. Furthermore, by configuring a sign of the nonlinear parameter K_{g} of the coupler 21 to be opposite each other to either K₁ or K₂, at least part of a cross-Kerr interaction between the qubit 20 and the coupler 21 (two out of the four combinations for the sum of the nonlinear parameters of the qubit 20 and the coupler 21) can be suppressed. A cross Kerr interaction between the qubit 20 and the coupler 21 may be abbreviated as “QC-CKI”. Note that in equation (25), when K₁=K₃ and K₄=K₂, h⁽⁴⁾ becomes zero.

When a condition for the resonance angular frequencies ωᵢ to ω₄ of the four qubits to be coupled via the four-body interaction is set as

ω₁+ω₄=ω₂+ω₃ (29)

equation (13) may be expressed as the following equation (30).

$${h}^{( 4 )} = - 2 {g}_{12} {g}_{13}^{2} \frac{( {K}_{1} - {K}_{4} ) {Δ}_{23} + ( {K}_{3} - {K}_{2} ) {Δ}_{14}}{{Δ}_{12} {Δ}_{13} {Δ}_{14} {Δ}_{23}} \qquad ( 30 )$$

From equation (30), when

K₁=K₃=K>0, K₂=K₄=−K<0 (31a)

or

K₁=K₃=K<0, K₂=K₄=−K>0 (31b)

holds, then,

(K₁−K₄)>0, (K₃−K₂)>0 (32a)

or

(K₁−K₄)<0, (K₃−K₂)<0 (32b)

Thus, setting differences in resonance angular frequencies Δ₂₃ and Δ₁₄ such that:

Δ₂₃>0, Δ₁₄>0 (33a)

or

Δ₂₃<0, Δ₁₄<0 (33b)

may enlarge a value (or an absolute value if negative) of the numerator term in equation (30): (K₁−K₄)Δ₂₃+(K₃−K₂)Δ₁₄. The coupling coefficient h⁽⁴⁾ of the four-body interaction induced by the nonlinearity of the four qubits 20-1 to 20-4 can be increased. Based on equations (31a) and (31b), it is possible to suppress a part of a cross Kerr interaction between qubits 20 (abbreviated as “QQ-CKI”) (four out of the six combinations for the sum of the nonlinear parameters of the two qubits 20). By configuring a sign of the nonlinear parameter K_{g} of the coupler 21 to be opposite each other to either K₁ or K₂ both having opposite signs, it is possible to suppress a part of the cross Kerr interaction (QC-CKI) between the qubit 20 and the coupler 21 (two out of the four combinations for the sum of the nonlinear parameters of the qubit 20 and the coupler 21). Note that in equation (30), when K₁=K₄ and K₃=K₂, the coupling coefficient h⁽⁴⁾ becomes 0.

According to the present disclosure, it is possible to make a many-body interaction of qubits appear in various scenarios (cases) and to simplify setting of an interaction strength, i.e., a coupling coefficient.

The nonlinear parameter Kᵢ of qubits 20-i (i=1, 2, 3, 4) can be broadly categorized into a component determined by an inductance and a component determined by a capacitance. For example, nonlinear parameter Kᵢ may be expressed by the following equation (18).

Kᵢ=pᵢE_{ci} (34)

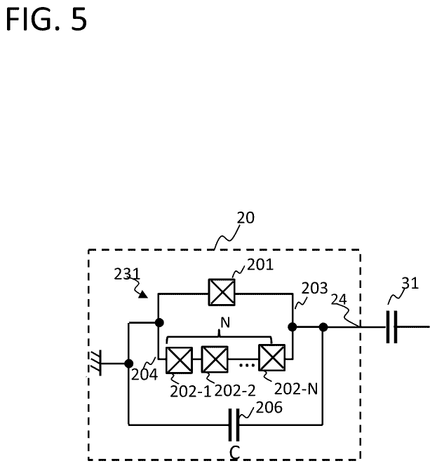

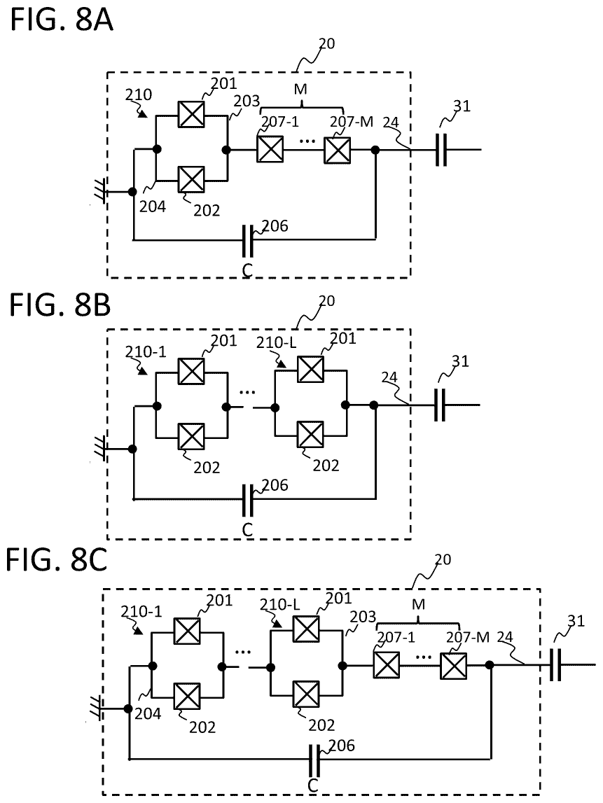

In equation (34),
pᵢ (Participation ratio) is a ratio of an inductive energy stored in the qubit (Josephson junction) to an inductive energy stored in the circuit, and may be given, for example, as follows.

$${p}_{i} = \frac{{n}_{iS} {L}_{iS}^{3} + {n}_{iJ} {L}_{iJ}^{3}}{{( {L}_{iL} + {n}_{iS} {L}_{iS} + {n}_{iJ} {L}_{iJ} )}^{3}} \qquad ( 35 )$$

where,
L_{iL} (i=1, 2, 3, 4) is a structural inductance of the i-th qubit 20-i,
L_{iS} (i=1, 2, 3, 4) is an inductance of a SQUID for the i-th qubit 20-i,
n_{iS} (i=1, 2, 3, 4) is the number of SQUIDs in the i-th qubit 20-i (FIG. 8B and FIG. 8C),
L_{iJ} (i=1, 2, 3, 4) is an inductance of a Josephson junction connected in series with the SQUID in the i-th qubit 20-i (FIG. 8A, FIG. 8C), and
n_{iJ} (q=1, 2, 3, 4) is the number of Josephson junctions (FIG. 5) connected in series in the i-th qubit 20-i.

E_{Ci} in equation (34) may be given by the following equation (36).

$${E}_{Ci} = \frac{{e}^{2}}{2 {C}_{i}} ( i = 1 , 2 , 3 , 4 ) \qquad ( 36 )$$

where e is the elementary charge, and Cᵢ is an effective structural capacitance of qubit 20. For example, Cᵢ may be a capacitance of a capacitor 206 (shunt capacitor) of the i-th qubit 20-i.

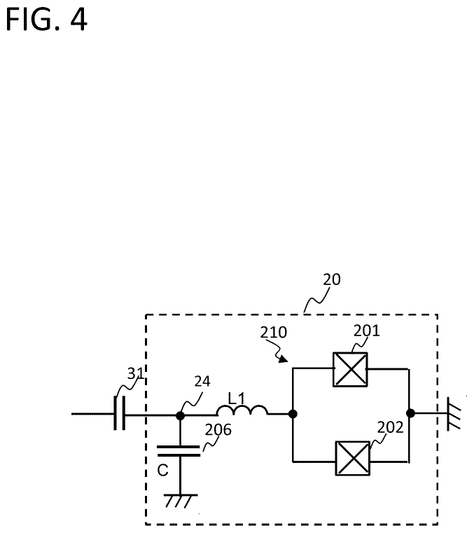

FIG. 4 illustrates a structural inductance of the SQUID 210 for qubit 20. The maximum value of pᵢ (i=1, 2, 3, 4) in equation (35) is 1. To bring pᵢ closer to its maximum value, the structural inductance Lᵢ (inductance L1 in FIG. 4) needs to be reduced as much as possible.

One or more of the four qubits 20 may be configured as a JPO including a SNAIL (Superconducting Nonlinear Asymmetric Inductive eLement), as illustrated in FIG. 5. Referring to FIG. 5, a SNAIL 231 may include a small Josephson Junction 201 in parallel with large Josephson Junctions 202-1 to 202-N connected in series in a large number N (N≥1). A Josephson energy E_{J} of Josephson Junction 201 is a times (0<α<1) a Josephson energy E_{J} of each Josephson Junction 202-1 to 202-N.

Since the Josephson energy is proportional to a critical current, a critical current of Josephson Junction 201 is α times (0<α<1) a critical current I_{c} of each Josephson Junction 202-1 to 202-N. A value of the critical current of a Josephson Junction is proportional to a junction size (junction area) of a Josephson Junction. Therefore, a junction size of the Josephson Junction 201 is smaller than each of junction sizes of Josephson Junctions 202-1 to 202-N. The junction size of Josephson Junction 201 is α times (0<α<1) the each of junction sizes of Josephson Junctions 202-1 to 202-N. Connecting Josephson Junctions 202-1 to 202-N in series may contribute to reduction nonlinearity of the SNAIL 231.

When a Hamiltonian Hi of the i-th qubit 20-i (i=1, . . . , 4) is expressed by the following equation (41),

$${H}_{i} = {ω}_{i} {a}_{i}^{†} {a}_{i} + {{g}_{3 i} ( {a}_{i} + {a}_{i}^{†} )}^{3} + {{g}_{4 i} ( {a}_{i} + {a}_{i}^{†} )}^{4} \qquad ( 37 )$$

the nonlinear parameter Kᵢ (i=1, . . . , 4) representing a nonlinearity (Kerr nonlinearity) of the i-th qubit 20-i using a SNAIL, may be given by the following equation (38) (Reference Literature 1). In equation (37), ai⁺ and ai are creation and annihilation operators for a boson in the i-the qubit 20-i.

$${K}_{i} = 12 ( {g}_{4 i} - \frac{5 {g}_{3 i}^{2}}{{ω}_{i}} ) \qquad ( 38 )$$

where ωᵢ is a resonance angular frequency of the i-th qubit 20-i.

Similarly, the parameter (Kerr coefficient) (nonlinear parameter) K_{g} representing a nonlinearity of the coupler 21 using a SNAIL may be expressed by the following equation (39).

$${K}_{g} = 12 ( {g}_{4 g} - \frac{5 {g}_{3 g}^{2}}{{ω}_{g}} ) \qquad ( 39 )$$

where ω_{g} is a resonance angular frequency of the coupler 21.

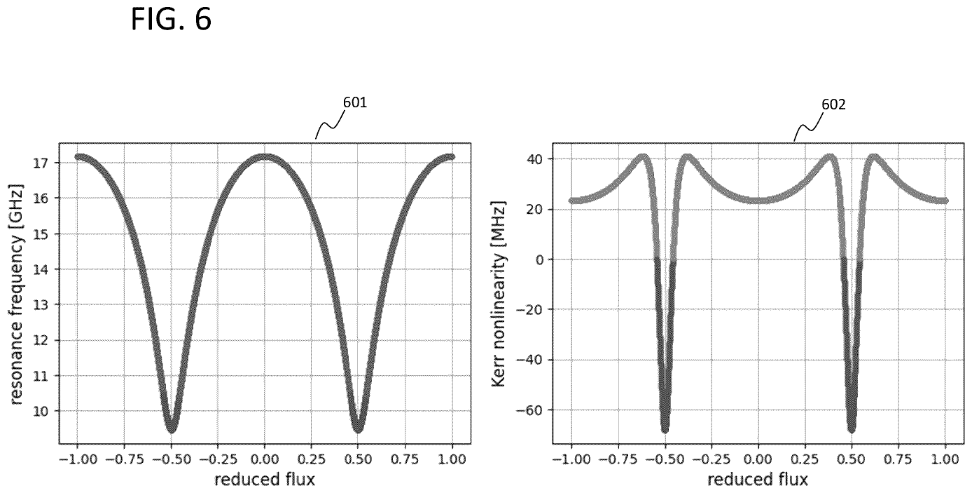

FIG. 6 shows an example of a magnetic field characteristic of the resonance frequency (GHz (Giga-Hertz)) (magnetic field response) 601 of a SNAIL and a magnetic field characteristic of the Kerr nonlinearity (MHz (Mega-Hertz)) (magnetic field response) 602 of a SNAIL. In graphs 601 and 602, a horizontal axis is a reduced flux (Φ/Φ₀, where Φ₀ is a magnetic flux quantum). For a JPO using a SNAIL with a negative nonlinear parameter, K becomes the minimum (locally minimum) when the magnitude of the applied magnetic flux is at a position where the resonance frequency of the JPO using the SNAIL (qubit) takes a minimum value (magnetic flux Φ=±0.5Φ₀ (half-integer) (where Φ₀ is a magnetic flux quantum Φ₀=h/2e)). JPO using a SNAIL with a positive nonlinear parameter K operates outside the ±0.5 (half-integer) range of the applied magnetic flux (Φ=0.4 to −0.4Φ₀, 0.6 to 1.4Φ₀, −0.6 to −1.4Φ₀). Note that a SQUID cannot change the sign of the nonlinear parameter in the applied magnetic field.

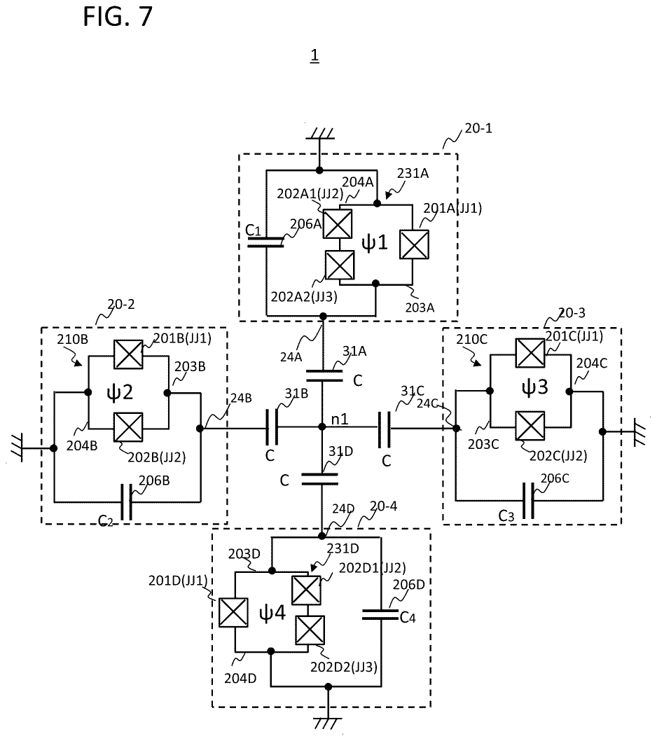

FIG. 7 illustrates a configuration in the circuit of FIG. 3, where the first qubit 20-1 and the fourth qubit 20-4 are formed by JPOs including SNAILs 231A and 231D, respectively, while the second qubit 20-2 and the third qubit 20-3 are formed by JPOs including SQUIDs 210B and 210C, respectively. Furthermore, the JPOs including SNAILs 231A and 231D oscillate (parametrically oscillate) due to capacitively coupled AC signals. For example, an AC signal (at twice the resonance frequency) supplied from a signal source (not shown) is applied via capacitive coupling to each of the electrodes 24A and 24D of the first qubit 20-1 and the fourth qubit 20-4.

The nonlinear parameters K₁ and K₂ of the first qubit 20-1 and the second qubit 20-2, respectively, are assumed to have opposite signs (e.g., K₂ is positive, K₁ is negative). and the nonlinear parameters K₃ and K₄ of the third qubit 20-3 and the fourth qubit 20-4 are assumed to have opposite signs (e.g., K₃ is positive and K₄ is negative). In this case, in equation (6), (K₂−K₁) is positive, (K₃−K₄) is also positive, and the difference Δ₃₄ between the resonance angular frequencies of the third qubit 20-3 and the fourth qubit 20-4, and the difference Δ₁₂ between the resonance angular frequencies of the first qubit 20-1 and the second qubit 20-2, have the same sign (both positive or both negative), a value of (K₂−K₁)Δ₃₄+(K₃−K₄)Δ₁₂ (absolute value if negative) is large, and the coupling coefficient h⁽⁴⁾ of the four-body interaction due to nonlinearity of the qubit 20 is large. Though not particularly limited, the SNAIL 231A of the first qubit 20-1 and the SNAIL 213D of the fourth qubit 20-4 may be supplied respectively with magnetic fields φ₁ and φ₄ from an unillustrated magnetic field application parts (inductors each with one end connected to a signal line and the other end connected to ground) such that the nonlinear parameters K₁ and K₄ have negative signs. The SQUID 210B of the second qubit 20-2 and the SQUID 210C of the third qubit 20-3 may be respectively supplied with magnetic fields #₂ and #3 from an unillustrated magnetic field application parts (inductors each with one end connected to a signal line and the other end connected to ground) (the magnetic field may be, for example, a superposition of a bias (DC) magnetic field and an AC magnetic field) to parametrically oscillate.

In FIG. 7, as in FIG. 4, since no coupler is included, QC-CKI does not exist. QQ-CKI is proportional to a sum of the nonlinearity of qubits 20. QQ-CKI has 4!/2!=4×3/2=6 combinations (types), which are respectively proportional to:
(K₁+K₂);
(K₁+K₃);
(K₁+K₄);
(K₂+K₃);
(K₂+K₄); and
(K₃+K₄).

As an example case, when the nonlinear parameters K₁ to K₄ of the first to fourth qubits 20-1 to 20-4 are configured to

K₂>0, K₁=−K₂<0, K₃>0, K₄=−K₃<0 (40),

(K₁+K₂) and (K₃+K₄) become zero. Since K₁ and K₃ have opposite signs and K₃ and K₄ have opposite signs, (K₁+K₃) and (K₂+K₄) become smaller compared to a case where K₁ and K₃ are of the same sign and K₃ and K₄ are of the same sign, thus suppressing QQ-CKI. In FIG. 7, all of the first to fourth qubits 20-1 to 20-4 may also be configured to include a SNAIL as a nonlinear element.

As a configuration for altering the nonlinearity in the first to fourth qubits 20-1 to 20-4, a configuration such as those illustrated in FIG. 8A, FIG. 8B, or FIG. 8C may also be used. FIG. 8A illustrates a configuration of a qubit 20 where M Josephson Junctions 207-1 to 207-M are connected in series with the SQUID 210 between the electrode 24 and ground. By changing the number M of Josephson Junctions 207-1 to 207-M, the nonlinearity (Kerr nonlinearity) of the qubit 20 can be altered. For example, as the number M increases, the nonlinearity decreases. FIG. 8B illustrates a configuration of a qubit 20 where L SQUIDs 210-1 to 210-L are connected in series between the electrode 24 and ground. By changing the number L of SQUIDs 210-1 to 210-L, the nonlinearity (Kerr nonlinearity) of the qubit 20 can be altered. As the number L increases, nonlinearity decreases. FIG. 8C illustrates a configuration of a qubit 20 where M Josephson Junctions 207-1 to 207-M are connected in series with L SQUIDs 210-1 to 210-L between the electrode 24 and ground. By changing the number L of SQUIDs 210-1 to 210-L and the number M of Josephson Junctions 207-1 to 207-M, the nonlinearity (Kerr nonlinearity) of the qubit 20 can be altered.

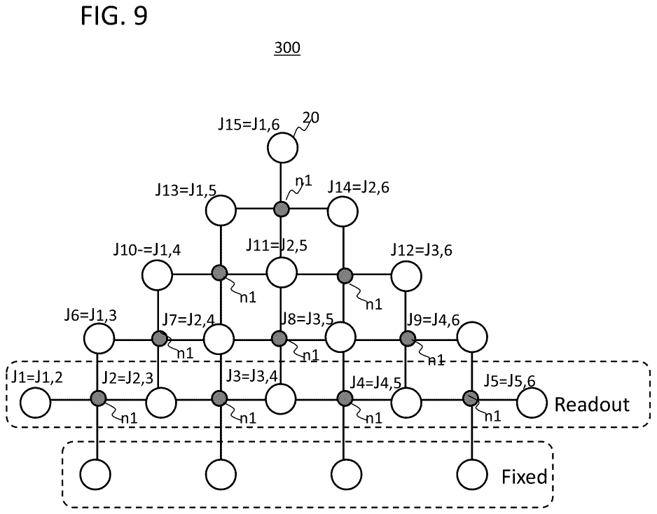

FIG. 9 is a diagram illustrating an example configuration of a four-body coupled quantum computing apparatus (quantum annealing machine) 300. FIG. 9 illustrates a configuration in which a circuit configuration of embodiments described with reference to FIGS. 2, 3, 7, etc., as a basic circuit (basic unit, plaquette), is extended to multiple bits. As illustrated in FIG. 9, the basic circuit can be expanded to construct a large-scale circuit. FIG. 9 illustrates an example of a physical implementation of the LHZ scheme (logical bit count N=6, physical bit count=15) disclosed in NPLs 1 and 2, etc. In FIG. 9, each circle represents a qubit 20, which is a physical qubit and a gray circle represents a coupler 2.

A Hamiltonian for all-to-all Ising spin glass model may be given by the following equation (41).

$${H}_{f} = {\sum }_{i = 1}^{N - 1} {\sum }_{i < j}^{N} {J}_{ij} {σ}_{z}^{( i )} {σ}_{z}^{( j )} + {\sum }_{i = 1}^{N} {b}_{i} {σ}_{z}^{( i )} \qquad ( 41 )$$

where σ⁽ⁱ⁾z is a spin operator (Pauli matrix z-component),
Jᵢⱼ is an interaction coefficient, and
bᵢ is a local magnetic field.

Equation (41) may be expanded to a physical qubit Hamiltonian given by the following equation (42), with K=N(N−1)/2 (for N=6, K=15).

$${H}_{p} = {\sum }_{k = 1}^{K} {J}_{k} {\tilde{σ}}_{z}^{( k )} + {\sum }_{l = 1}^{K - N + 1} {C}_{l} = {\sum }_{k = 1}^{K} {J}_{k} {\tilde{σ}}_{z}^{( k )} - ( C {\sum }_{l = 1}^{K - N + 1} {\tilde{σ}}_{z}^{( l , n )} {\tilde{σ}}_{z}^{( l , e )} {\tilde{σ}}_{z}^{( l , s )} {\tilde{σ}}_{z}^{( l , w )} ) \qquad ( 42 )$$

The interaction coefficient (matrix) Jᵢⱼ of the fully connected Ising spins in equation (41) is transformed to a local magnetic field Jₖ acting on a physical qubit in the Hamiltonian of equation (42). C₁ in equation (42) is a constraint (see Non-Patent Literature 1). In equation (42),

$${\tilde{σ}}_{z}^{( k )}$$

is a kth physical spin (Pauli matrix z component). C₁ (1∈{1, . . . ,K−N+1}) in equation (42) are constructed from conditions on closed loops of logical qubits with necessary requirements (i) that the constraints cover all physical qubits and (ii) that the number of constraints is at least K−N. An example of a four-body interaction is illustrated. Note that (1,n), (1,e), (1,s), (1,w) represent the 1-th plaquette (a region enclosed by four physical qubits connected to common node n1), where n, e, s, w denote the four physical qubits located east, west, south, and north relative to node n1. For the configuration in FIG. 9, the total number of constraints in equation (42) is K−N+1=15−6+1=10, consisting of the sum of constraints C₁ to C₁₀. Nine distinct frequencies are assigned to prevent an occurrence of an extra four-body interaction, and the numbers 1 to 9 within each circle (physical qubit) represent labels for the nine different frequencies. The bottom row of four qubits holds fixed values, and a solution to the optimization problem is read out from the row one above the bottom.

In the present disclosure, a quantum circuit apparatus may be integrated as a chip. In this case, a substrate may be silicon (Si), for example, but other electronic materials such as sapphire or compound semiconductor materials (Group IV, Group III-V, Group II-VI) may also be used. Furthermore, while a single-crystal substrate is preferable for a quantum chip, a polycrystalline or amorphous substrate may also be used. Wiring layer pattern on a quantum chip may be formed by deposition (vapor-deposition) of a superconducting material onto a substrate surface and then patterning thereof. As for a superconducting material(s) (interconnect material(s)) used in an interconnect(s) and an electrode(s) in an interconnect layer of a quantum chip, a material(s) such as Nb (niobium) or Al (aluminum) may be employed, though not limited thereto. Niobium nitride, indium (In), lead (Pb), tin (Sn), rhenium (Re), palladium (Pd), titanium (Ti), titanium nitride, molybdenum (Mo), tantalum (Ta), tantalum nitride, and alloys including at least one of these, or any other metal that is made in a superconducting state when cooled to an extremely low temperature (cryogenic temperature). As a Josephson junction, a first aluminum film may be formed on a surface of a substrate of a quantum chip by a first oblique epitaxy, oxidized to form a tunnel oxide film (AlOₓ), and a second aluminum film may be formed by a second oblique epitaxy from an opposite direction to the first oblique epitaxy, thereby forming a Josephson junction (Al/AlOₓ/Al).

While a SQUID and a SNAILs were used as examples of a nonlinear element for a qubit 20 and a coupler 21, ATS (Asymmetrically Threaded SQUID) or STS (Symmetrically Threaded SQUID) may also be used. Alternatively, any other configuration of a Josephson junction may be employed. For example, a qubit 20 may also include a transmon including a Josephson junction and a capacitor.

A cross-Kerr nonlinear interaction described above is not limited to a superconducting quantum circuit and may be also applicable to a cross-Kerr nonlinear interaction between an optical cavity and a microwave. That is, while a JPO is used as an example to illustrate a Kerr parametric oscillator (KPO) with a Kerr effect, it goes without saying that qubits 20-1 to 20-4 may also be implemented using KPO other than JPO.

### REFERENCE LITERATURE 1

Timo Hillmann, Fernando Quijandria, “Designing Kerr Interactions for Quantum Information Processing via Counterrotating Terms of Asymmetric Josephson-Junction Loops”, Phys. Rev. Applied 17, 064018—Published 9 Jun. 2022

The above embodiments/examples may be listed as the following supplementary notes (Notes), though not limited thereto.

(Note 1) A quantum circuit apparatus includes N qubits, where N is a predetermined integer of 3 or greater, configured to be coupled via a many-body interaction, wherein a parameter representing nonlinearity of at least one of the N qubits has a sign different from a sign of a parameter representing nonlinearity of at least one other of the N qubits.
(Note 2) In the quantum circuit apparatus according to Note 1, the N is set to 4 and the many-body interaction is a four-body interaction of four qubits, wherein the four qubits coupled via the four-body interaction are capacitively coupled to a common node, respectively.
(Note 3) In the quantum circuit apparatus according to Note 1 or 2, a coefficient representing a coupling coefficient of the four-body interaction of the four qubits is given as a combination of a term including a difference between parameters representing nonlinearity of two qubits and a term including a difference between parameters representing nonlinearity of remaining two qubits, wherein the two qubits are configured to have signs of the parameters representing nonlinearity of the two qubits set to be opposite each other, and wherein the remaining two qubits are configured to have signs of the parameters representing nonlinearity of the remaining two qubits set to be opposite each other.
(Note 4) In the quantum circuit apparatus according to any one of Notes 1 to 3, at least one of the four qubits is configured such that the value and sign of the parameter representing the nonlinearity are variably set according to the magnetic field applied to said at least one qubit.
(Note 5) In the quantum circuit apparatus according to Note 2, the four qubits constitute a basic unit, wherein the quantum circuit apparatus includes a plurality of the basic units arranged to construct a quantum computer.
(Note 6) In the quantum circuit apparatus according to any one of Notes 1 to 5, the qubit includes at least one of: a Josephson junction; a SQUID (Superconducting Quantum Interference Device) with a plurality of Josephson junctions arranged in a loop; and a SNAIL (Superconducting Nonlinear Asymmetric Inductive eLement) including a loop in which at least one Josephson junction is connected in parallel to a plurality of Josephson junctions connected in series.
(Note 7) A control method of a quantum circuit that includes N qubits, where N is a predetermined integer of 3 or more, enabled to be coupled via a many-body interaction, the method comprising:
setting a sign of a parameter representing nonlinearity of at least one of the N qubits to be different from a sign of a parameter representing nonlinearity of at least one other of the N qubits, to increase a coupling coefficient of the many-body interaction of the N qubits.
   (Note 8) In the method according to Note 7, the N is set to 4 and the many-body interaction is a four-body interaction of four qubits.

### (Note 9]

In the method according to Note 8, the four qubits coupled via the four-body interaction are connected to a single common node, respectively.

The disclosures of each of the above-mentioned documents are hereby incorporated by reference into this document. Within the scope of the disclosure of the present application (including the claims), modifications, adjustments, and combinations of embodiments or examples based on the fundamental technical concept are possible. Furthermore, within the scope of the claims of the present disclosure, various combinations or selections of the disclosed elements (including each element of the appended claims, each element of the embodiments, each element of the drawings, etc.) are possible. That is, the present disclosure naturally encompasses the entire disclosure, including the claims, and various modifications and alterations that would be obvious to one skilled in the art based on the technical concept.

What is claimed is:

1. A quantum circuit apparatus comprising N qubits, where N is a predetermined integer of 3 or greater, configured to be coupled via a many-body interaction, wherein at least one of the N qubits is configured to have a sign of a parameter representing nonlinearity thereof different from a sign of a parameter representing nonlinearity of at least one other of the N qubits.

2. The quantum circuit apparatus according to claim 1, wherein the N is set to 4 and the many-body interaction is a four-body interaction of four qubits, wherein the four qubits to be coupled via the four-body interaction, are capacitively coupled to a common node, respectively.

3. The quantum circuit apparatus according to claim 2, wherein a coefficient representing a coupling coefficient of the four-body interaction of the four qubits is given as a combination of a term including a difference between parameters representing nonlinearity of two qubits and a term including a difference between parameters representing nonlinearity of remaining two qubits,
wherein the two qubits are configured to have signs of the parameters representing nonlinearity of the two qubits set to be opposite each other, and
wherein the remaining two qubits are configured to have signs of the parameters representing nonlinearity of the remaining two qubits set to be opposite each other.

4. The quantum circuit apparatus according to claim 1, wherein at least one of the four qubits is configured such that a value and a sign of the parameter representing the nonlinearity thereof are variably set according to a magnetic field applied thereto.

5. The quantum circuit apparatus according to claim 1, wherein a sign of the parameter (K₁) representing nonlinearity of a first qubit is set to be opposite to a sign of the parameter (K₂) representing nonlinearity of a second qubit, and
a sign of the parameter (K₃) representing nonlinearity of the fourth qubit is set to be opposite to a sign of the parameter (K₄) representing nonlinearity of a third qubit, and wherein for a difference Δ₃₄ between a resonance angular frequency (ω₃) of the third qubit and a resonance angular frequency (ω₄) of the fourth qubit, and a difference Δ₁₂ between a resonance angular frequency (ω₁) of the first qubit and a resonance angular frequency (ω₂) of the second qubit, values and signs of the parameters K₁, K₂, K₃ and K₄ representing the nonlinearity of the first, second, third and fourth qubits, respectively are set to increase a sum of (K₂−K₁)Δ₃₄ and (K₃−K₄)Δ₁₂.

6. The quantum circuit apparatus according to claim 2, wherein the four qubits constitute a basic unit, wherein the quantum circuit apparatus includes a plurality of the basic units arranged to construct a quantum computer.

7. The quantum circuit apparatus according to claim 1, wherein the qubit includes at least one of:
a Josephson junction;
a SQUID (Superconducting Quantum Interference Device) with a plurality of Josephson junctions arranged in a loop; and
a SNAIL (Superconducting Nonlinear Asymmetric Inductive eLement) including a loop in which at least one Josephson junction is connected in parallel to a plurality of Josephson junctions connected in series.

8. A control method of a quantum circuit that includes N qubits, where N is a predetermined integer of 3 or more, enabled to be coupled via a many-body interaction, the method comprising:
setting a sign of a parameter representing nonlinearity of at least one of the N qubits to be different from a sign of a parameter representing nonlinearity of at least one other of the N qubits, to increase a coupling coefficient of the many-body interaction of the N qubits.

9. The method according to claim 8, wherein the N is set to 4, and the many-body interaction is a four-body interaction of four qubits.

10. The method according to claim 8, comprising connecting the four qubits coupled via the four-body interaction to a common node, respectively.

11. The method according to claim 9, wherein a coefficient representing a coupling coefficient of the four-body interaction of the four qubits is given as a combination of a term including a difference between parameters representing nonlinearity of two qubits and a term including a difference between parameters representing nonlinearity of remaining two qubits, the method comprising:
configuring the two qubits to have signs of the parameters representing nonlinearity of the two qubits set to be opposite each other, and
configuring the remaining two qubits are configured to have signs of the parameters representing nonlinearity of the remaining two qubits set to be opposite each other.
